(19) United States
(12) Patent Application Publication
(10) Pub. No.: US 2007/0200223 A1
(43) Pub. Date: Aug. 30, 2007

(54) Semiconductor device and semiconductor module therewith

(75) Inventor: Atsuo Konishi, Osaka (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/700,106

(22) Filed: Jan. 31, 2007

(30) Foreign Application Priority Data
Feb. 24, 2006 (JP) 2006-048554

(51) Int. Cl. H01L 23/34

(52) U.S. Cl. 257/706

(57) ABSTRACT

A semiconductor device capable of dissipating heat with a high degree of efficiency without impairing the strength thereof is provided. The semiconductor device includes a semiconductor chip 2, a heatsink plate 1 overlapping a rear face of the semiconductor chip 2, and an adhesive 4 for adhesively fixing the semiconductor chip 2 and the heatsink plate 1 to each other. In the rear face of the semiconductor chip 2, there is formed a depressed portion 7 right under a heat generating portion 6 of the semiconductor chip 2. On the front face of the heatsink plate 1, there is formed a protruding portion 8 that is to fit in the depressed portion 7.

This nonprovisional application claims priority under 35 U.S.C. § 119(a) on Patent Application No. 2006-048554 filed in Japan on Feb. 24, 2006, the entire contents of which are hereby incorporated by reference.

### BACKGROUND OF THE INVENTION

1. Field of the Invention

The present invention relates to a semiconductor module, and more particularly to a semiconductor device having high heat-dissipation efficiency that includes a semiconductor chip, a heatsink plate fitted to the rear face of the semiconductor chip, and an adhesive for bonding them together and to a semiconductor module incorporating such a semiconductor device.

2. Description of Related Art

In recent years, the performance of semiconductor devices that include many semiconductor chips has increasingly been improved and has led to a trend where the amount of load current that flows through a semiconductor chip has been constantly increasing. Under such a trend, the amount of load current lost inside a semiconductor chip inevitably increases, and the load current lost inside the semiconductor chip is converted into heat, and this increases the amount of heat generated in the semiconductor chip itself and consequently that in the semiconductor device.

Meanwhile, electronic equipment has increasingly been miniaturized, inevitably resulting in the miniaturization of semiconductor devices mounted therein and of semiconductor chips constituting semiconductor devices. Such miniaturization decreases the area of space for dissipating heat from a semiconductor device, and this impairs the heat dissipation efficiency of the semiconductor device.

Under the circumstances described above, rises in temperature make it impossible to maintain a desired electric conductivity of a semiconductor chip, or thermal stress breaks the structure thereof. Thus, rises in temperature in a semiconductor chip cause the reliability of the semiconductor device to be deteriorated.

The above described inconveniences caused by the heat generated in a semiconductor chip have conventionally been coped with by making the surface area of a heatsink plate fitted to the rear face of the semiconductor chip or the land pattern thereof larger so as to promote natural cooling, or by additionally fitting a cooling fan or a cooling-medium-circulation unit to the semiconductor chip to achieve forcible cooling.

Both of the cooling methods described above, however, require upsizing of semiconductor devices or lead to rises in the prices thereof, and hence neither of them is likely to meet common demands. Recently, therefore, methods have been adopted such as: using a thin-film semiconductor substrate in a semiconductor chip so as to promote heat conduction; and forming grooves across the rear face of a semiconductor chip so as to obtain a larger heat dissipation area, and thereby to alleviate deformation caused by heat stress. These methods, which are disclosed in, for example, JP-A-2001-338932, help enhance the heat dissipation efficiency of semiconductor devices in their operation state, without upsizing them.

Inconveniently, however, making a semiconductor chip thinner or forming grooves on the rear face thereof for the purpose of promoting dissipation of the heat generated therein causes the strength thereof to be impaired, increasing chances of problems such as a cracking or a chipping during configuration thereof, which is significantly disadvantageous in terms of yields and fabrication efficiency. Put conversely, attempts to prevent yields from being decreased and fabrication efficiency from being impaired limit how thin the substrate can be made or how deep the grooves can be formed (the film thickness of the semiconductor chip).

### SUMMARY OF THE INVENTION

The present invention has been made in view of the above described inconveniences, and an object of the present invention is to provide, without impairing the strength of a semiconductor chip, a semiconductor device and a semiconductor module having high heat-dissipation efficiency.

To achieve the above object, according to the present invention, a semiconductor device is provided with a semiconductor chip, a heatsink plate fitted to the rear face of the semiconductor chip, and an adhesive for bonding the semiconductor chip and the heatsink plate to each other. Here, in the rear face of the semiconductor chip, there is formed a depressed portion exclusively in a part thereof right under a heat generating portion of the semiconductor chip. With this configuration, the distance from the heat generating portion to the adhesive is shortened and a wider area of the semiconductor chip comes in contact with the adhesive. As a result, the heat generated in the semiconductor chip is efficiently conducted to the adhesive and the heatsink plate, and thus improvement in the heat dissipation efficiency is realized. Furthermore, by forming, in addition to the depressed portion formed in the rear face of the semiconductor chip, the protruding portion in the heatsink plate fitted to the rear face with the adhesive laid therebetween such that the protruding portion fits in the depressed portion, it is possible to provide a semiconductor device having heat-dissipation efficiency even higher than that of the semiconductor device configured as described above. Thus, miniaturization of semiconductor devices, reduction of power loss therein, reduction of costs thereof, and reduction of prices thereof can be achieved.

### BRIEF DESCRIPTION OF THE DRAWINGS

These and other objects and features of the present invention will be apparent from the following detailed description of preferred embodiments thereof taken in conjunction with the accompanying drawings, in which:

FIG. 1 is a diagram showing a semiconductor module of a first embodiment of the present invention;

FIG. 2 is a sectional view taken along line A-A shown in FIG. 1;

FIG. 3 is a perspective view showing a semiconductor chip of the first embodiment;

FIG. 4 is a sectional view showing a semiconductor device of the first embodiment;

FIG. 5 is a diagram illustrating a fabrication flow of the first embodiment;

FIG. 6 is a perspective view showing a semiconductor chip of a second embodiment of the present invention;

FIG. 7 is a sectional view showing a semiconductor device of the second embodiment;

FIG. 8 is a perspective view showing a semiconductor chip of a third embodiment of the present invention;

FIG. 9 is a sectional view showing a semiconductor device of the third embodiment;

FIG. 10 is a perspective view showing a semiconductor chip of a fourth embodiment of the present invention;

FIG. 11 is a sectional view showing a semiconductor device of the fourth embodiment;

FIG. 12 is a perspective view showing a semiconductor chip of a fifth embodiment of the present invention;

FIG. 13 is a sectional view showing a semiconductor device of the fifth embodiment;

FIG. 14 is a top view showing an electrode formed on the front face of the semiconductor chip of the fifth embodiment of the present invention;

FIG. 15 is a sectional view showing a semiconductor device of a sixth embodiment;

FIG. 16 is a diagram showing a modified example of the sixth embodiment of the present invention;

FIG. 17 is a diagram showing a modified example of the sixth embodiment of the present invention;

FIG. 18 is a diagram showing a modified example of the sixth embodiment of the present invention;

FIG. 19 is a diagram showing a modified example of the sixth embodiment of the present invention;

FIG. 20 is a perspective view showing a semiconductor chip of a seventh embodiment of the present invention; and

FIG. 21 is a sectional view of a semiconductor device of the seventh embodiment of the present invention.

### DETAILED DESCRIPTION OF PREFERRED EMBODIMENTS

Hereinafter, the best mode for carrying out the present invention will be described in detail by way of embodiments shown in the drawings 1 to 21. It should be understood, however, that these embodiments exemplify the technological ideas of the present invention and that the present invention is not meant to be limited to these embodiments. It should also be understood that the present invention may be equally practiced with many modifications and variations made within the technological idea described in the appended claims.

In devising the present invention, the inventor of the present invention paid attention to a heat generating portion of a semiconductor chip where heat is generated when a semiconductor device incorporating the semiconductor chip is in operation. Particularly in a semiconductor chip incorporated in a voltage controlling device, which actively uses power loss to control operation, the power loss is directly converted to heat, resulting in generation of a large amount of heat. When the amount of heat accumulated therein exceeds a predetermined value, it is difficult to supply a desired voltage, and this impairs the operation of the semiconductor device. Here, it is often the case that the heat generating portion of the semiconductor chip is an electrode formation area located on the front face of the semiconductor chip. Furthermore, in the electrode formation area, a wire connecting portion generates a particularly large amount of heat because of increased current density. Thus, the amount of heat generated in a semiconductor chip is position-dependent, which means that the amount of heat generation differs depending on the position on the surface of the semiconductor chip.

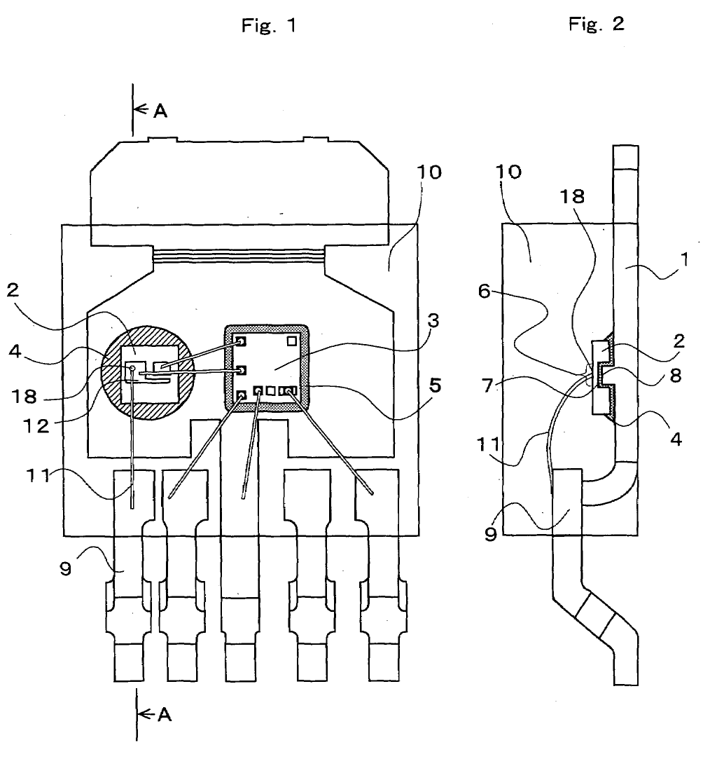

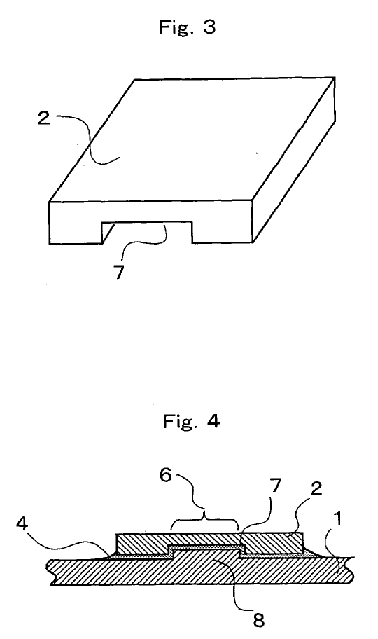

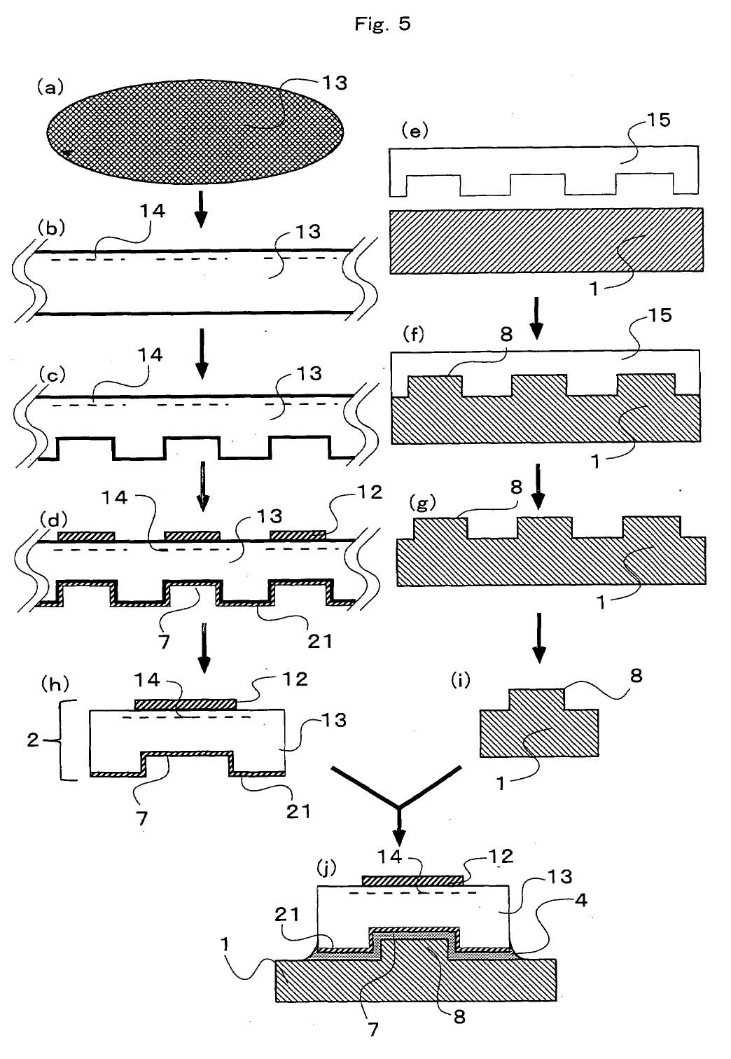

First, a description will be given of a semiconductor device of a first embodiment of the present invention and a semiconductor module incorporating the semiconductor device. FIG. 1 is a top view showing the exterior of the resin-sealed-type semiconductor module of the present embodiment. FIG. 2 is a sectional view taken along line A-A shown in FIG. 1. FIG. 3 is a perspective view showing a semiconductor chip of the present embodiment. FIG. 4 is a sectional view showing the semiconductor device of the present embodiment. FIG. 5 is a diagram illustrating the fabrication flow of the present embodiment. The reference numeral 1 denotes a heatsink plate, the reference numerals 2 and 3 denote semiconductor chips, the reference numerals 4 and 5 denote adhesives, the reference numeral 6 denotes a heat generating portion, the reference numeral 7 denotes a depressed portion, the reference numeral 8 denotes a protruding potion, the reference numeral 9 denotes lead terminals, the reference numeral 10 denotes a mold resin, the reference numeral 11 denotes wires, the reference numeral 12 denotes an electrode, the reference numeral 13 denotes a wafer, the reference numeral 14 denotes a chip circuit, the reference numeral 15 denotes a mold, the reference numeral 16 denotes a base electrode, the reference numeral 17 denotes an emitter electrode, the reference numeral 18 denotes wire connecting positions, the reference numeral 19 denotes a bonding pad area, the reference numeral 20 denotes a through-hole, and the reference numeral 21 denotes a rear-face electrode.

As shown in FIGS. 1 to 4, in the semiconductor module of the present embodiment, on the front face of each of the plate-shaped semiconductor chips 2 and 3, there is formed an electrode, and the electrode formation area is the heat generating portion 6. The semiconductor chip 2 (hereinafter, no description will be given of the semiconductor chip 3, which is similar to the semiconductor chip 2) on the rear face of which the depressed portion 7 is selectively formed so as to be located right under the heat generating portion 6 and the heatsink plate 1 on the front face of which the protruding portion 8 is formed so as to fit in the depressed portion 7 are bonded together with the adhesive 4 in a position where the depressed portion 7 and the protruding portion 8 fit together. The semiconductor device is constituted of the semiconductor chip 2 and the heatsink plate 1 that are bonded together with the adhesive 4 laid therebetween as described above. The lead terminals 9 are each electrically connected to the electrode formation area with the wires 11. The semiconductor chip 2, the adhesive 4, the heatsink plate 1, the wires 11, and part of each lead terminal 9 are sealed in the mold-resin 10. Here, it is preferable that, as the adhesive 4, a material be used that has a heat conductivity higher than that of the material of the substrate forming the semiconductor chip 2 (e.g., silicon), examples including solder, silver paste, and the like.

With this configuration, the distance from the heat generating portion 6 on the front face of the semiconductor chip 2 and the heatsink plate 1 (highly thermally conductive member) is shortened, and thus a semiconductor device having high heat dissipation efficiency can be fabricated. Furthermore, forming the depressed portion 7 exclusively in the area right under the heat generating portion 6 of the semiconductor chip 2 makes it possible to form fewer depressed portions 7 than conventionally required. Moreover, the ratio of the area of the depressed portion 7 to the whole area of the rear face of the semiconductor chip 2 can be made smaller than conventionally required. These advantages make it possible to prevent the surface strength of the semiconductor chip 2 from being impaired. Thus, cracking and a chipping can be prevented during the fabrication process, and thus yields can be improved. In addition, no cooling device is externally added thereto, and this makes it possible to miniaturize the semiconductor device.

Now, a brief description will be given of an example of the fabrication process of the principle configuration of the present embodiment. First, as shown in FIGS. 5A and 5B, the wafer 13 is prepared on which the chip circuit 14 is formed (FIG. 5B and the subsequent drawings are enlarged sectional views). Next, as shown in FIG. 5C, in the wafer 13, within the area thereof where the chip circuit 14 is formed, part of the rear face thereof right under a highly heat generating portion (the heat generating portion 6, not illustrated in FIG. 3) is carved. Then, as shown in FIG. 5D, the electrode 12 and the rear-face electrode 21 are formed by vacuum deposition or the like.

With respect to the heatsink plate 1, as shown in FIG. 5E, the mold 15 produced beforehand and a plate-shaped heatsink plate 1 made of a highly thermally conductive material such as copper are prepared. Then, as shown in FIGS. 5F and 5G, the mold 15 is pressed into heatsink plate 1, and thus the protruding portions 8 are formed on the front face of the heatsink plate 1. As shown in FIGS. 5H and 5I, by dicing or the like, the wafer 13 is divided into individual semiconductor chips 2, and the heatsink plate 1 is divided into individual heatsink plates 1 having a desired size.

Finally, as shown in FIG. 5J, with the adhesive 4, the semiconductor chip 2 and the heatsink plate 1 are bonded together. Thus, the semiconductor device of the present embodiment is fabricated.

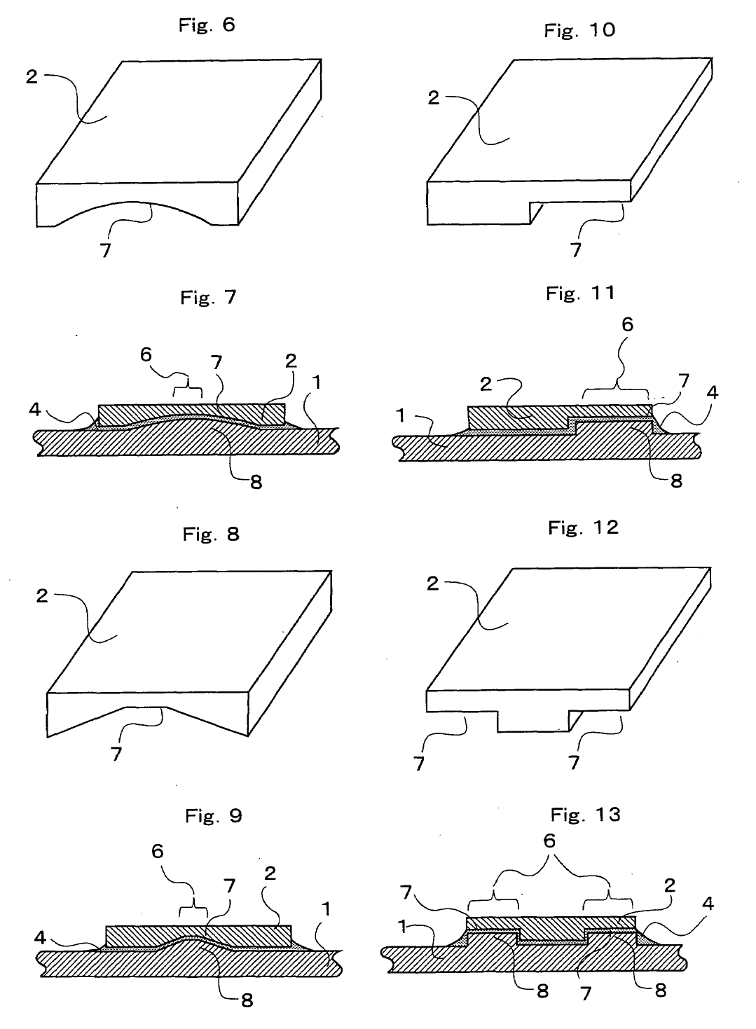

Next, a second embodiment of the present invention will be described with reference to FIGS. 6 and 7. In FIGS. 1 to 21, such portions as have the same name and the same function are identified with a common reference numeral, and no overlapping description will be repeated. The same applies to the third and subsequent embodiments, which will be described later.

The second embodiment is characterized in that the depressed portion 7 formed in the rear face of the semiconductor chip 2 and the protruding portion 8 of the heatsink plate 1 are shaped differently from those of the first embodiment. That is, as shown in FIG. 6, the depressed portion 7 is formed to have a hemispherical surface and the protruding portion 8 of the heatsink plate 1 is formed to have a hemispherical surface. With this configuration, the distance from the heat generating center such as the wire connecting portion 18 to the heatsink plate 1 (highly thermally conductive member) is shortened, and a semiconductor device having high heat dissipation efficiency can be provided. Furthermore, compared with the first embodiment, stress is alleviated more effectively and chances are reduced for cracks and chips to occur during the fabrication process, and hence the semiconductor chip 2, the semiconductor device as a whole, and furthermore the semiconductor module can be expected to be made thinner.

Next, the third embodiment of the present invention will be described with reference to FIGS. 8 and 9. The third embodiment is characterized in that the depressed portion 7 formed in the rear face of the semiconductor chip 2 and the protruding portion 8 of the heatsink plate 1 are shaped differently from those of the first embodiment. That is, the depressed portion 7 and the protruding portion 8 are formed to have a V-letter shape in cross-section. With this configuration, a semiconductor device having as high heat dissipation efficiency as those of the above described first and second embodiments have can be provided. This embodiment is particularly effective in a case where the amount of generated heat is gradually distributed on the surface of the semiconductor chip 2 around a given position thereon as the center.

Next, a fourth embodiment of the present invention will be described with reference to FIGS. 10 and 11. FIG. 10 shows the shape of the semiconductor chip 2 in the case where the heat generating portion 6 is lopsidedly located at one side of the front face thereof. As in the first to third embodiments, in the front face of the heatsink plate 1, as shown in FIG. 11, the protruding portion 8 is formed to be fitted in the depressed portion 7 formed in the rear face of the semiconductor chip 2. In this case, too, carving the rear face of the semiconductor substrate, exclusively in the part thereof that is located right under the heat generating portion 6, makes it possible to make the semiconductor chip 2 thinner and to enhance the heat dissipation efficiency thereof.

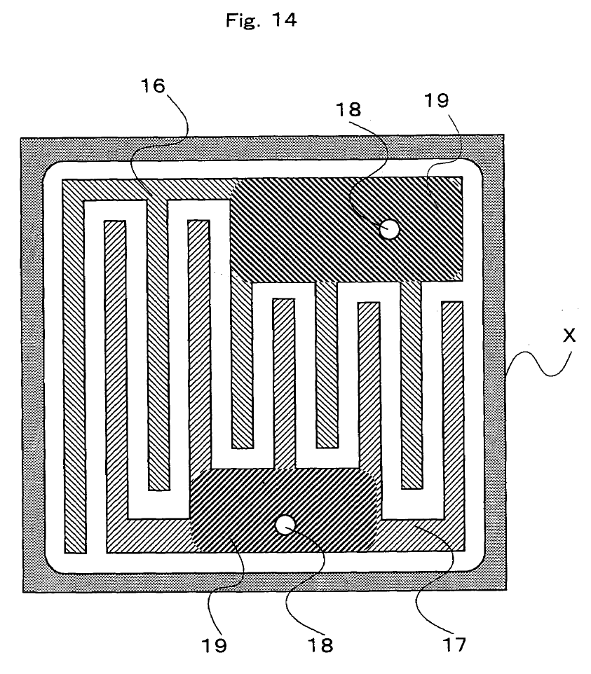

Next, a fifth embodiment of the present invention will be described with reference to FIGS. 12 to 14. FIG. 12 shows the shape of the semiconductor chip 2 in the case where the heat generating portion 6 is lopsidedly located close to each of two face-to-face edges of the front face thereof. FIG. 13 is a sectional view of the semiconductor device of the present embodiment. FIG. 14 is a top view showing an example of the configuration of an electrode formed on the front face of the semiconductor chip 2 of the present embodiment. In the case where the base electrode 16 and the emitter electrode 17 are formed as shown in FIG. 14, the area where a particularly large amount of heat is generated is the bonding pad areas 19 and 19, where the current density increases. This is because the increased current density causes the scattering probability of electrons to increase and the energy lost through the resulting increased scattering of electrons is converted into heat. When viewed from the side X of the semiconductor chip 2, the bonding pad areas 19 and 19 appear are located at both ends of the semiconductor chip 2. Thus, the shape of the semiconductor chip 2 shown in FIG. 12 helps achieve high heat dissipation efficiency.

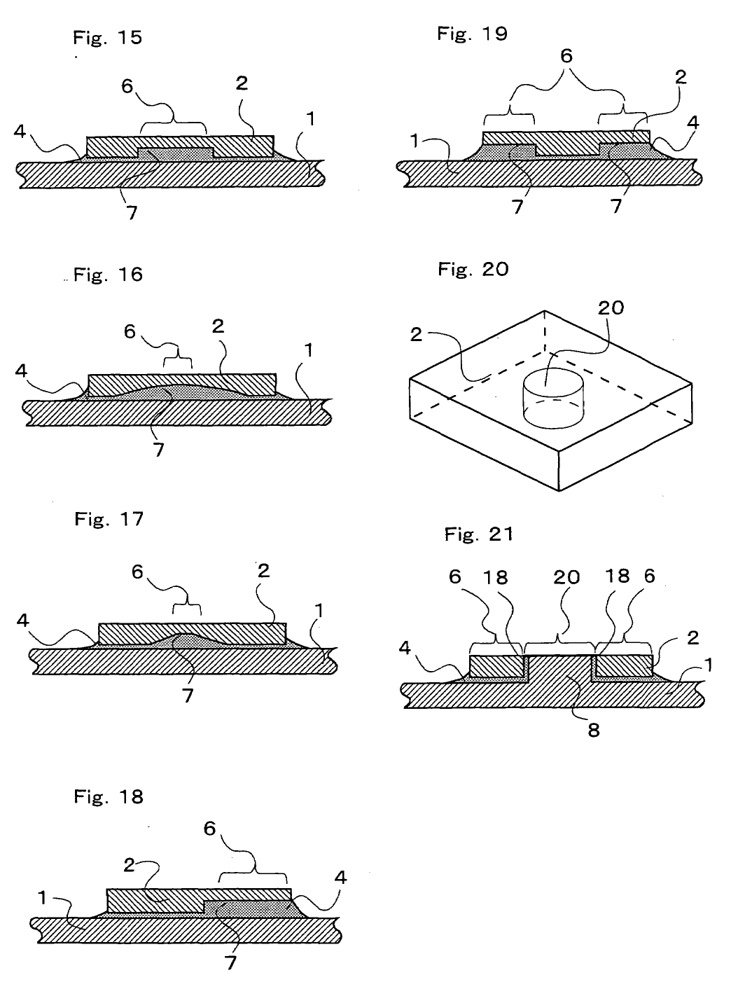

Next, a sixth embodiment of the present invention will be described with reference to FIG. 15. In the first embodiment, the depressed portion 7 of the semiconductor chip 2 and the protruding portion 8 of the heatsink plate 1 fit together. By contrast, the present embodiment is characterized in that the depressed portion 7 is filled with an adhesive 4 having a thermal conductivity higher than that of the semiconductor substrate material (e.g., silicon) forming the semiconductor chip 2. That is, no protruding portion 8 is formed on the front face of the heatsink plate 1. With this configuration, the fabrication process shown in FIG. 3 does not need to include the formation of the protruding portion of the heatsink plate 1, and this helps reduce the fabrication cost. Needless to say, a similar modification can be adopted on the second to fifth embodiments, making it possible to reduce the fabrication cost without losing their advantages (see FIGS. 16 to 19).

Next, a seventh embodiment of the present invention will be described with reference to FIGS. 20 and 21. In each of the first to sixth embodiments of the present invention, the heat generating portion 6 is identified and the portion right under the heat generating portion 6 is worked into a certain shape. Depending on the shape of the semiconductor chip 2 or the location of the heat generating portion, however, higher heat dissipation efficiency can be obtained by adopting a shape where, as shown in FIGS. 20 and 21, a through-hole 20 is formed in a part of the semiconductor chip 2 that does not contribute to the operation of the semiconductor device and into the through-hole 20, a depressed portion 8 of a heatsink plate 1 is inserted. In a conventional semiconductor chip on which a dead space exists, providing a heatsink plate 1 so as to penetrate the dead space makes it possible to provide the heatsink plate 1 closer to the heat generating portion 6.

Also, as described above, the heat generating portion 6 of the semiconductor chip 2 is mainly the electrode formation area, and in the electrode formation area, particularly at the wire connecting portion 18, where the current density is particularly high, the temperature becomes particularly high. Here, the electrode formation area is dependent on the circuit configuration in the semiconductor chip 2. In other words, the electrode formation area cannot be located freely. However, the wire connecting position 18 in the electrode formation area can be located freely within the bonding pad area 19 formed in the electrode. Thus, by designing the semiconductor chip 2 such that the wire connecting position 18 is located selectively in the vicinity of the through-hole, it is possible to achieve higher heat dissipation efficiency.

As has been described above, with respect to the semiconductor 2 incorporated in the semiconductor device, the heat generating portion 6 of the semiconductor chip 2 during the operation of the semiconductor device can now be identified. Thus, it is possible to fabricate a semiconductor device and a semiconductor module having high heat dissipation efficiency by: forming a depressed portion 7 selectively so as to be located right under the heat generating portion 6 (making only the heat generating portion 6 thinner) and bonding the heatsink plate 1 in which the protruding portion 8 is formed so as to fit in the depressed portion 7 and the rear face of the semiconductor chip 2 to each other with the adhesive 4; or forming the depressed portion 7 selectively so as to be located right under the heat generating portion 6 (making only the heat generating portion 6 thinner) and filling the depressed portion 7 with the highly-thermally-conductive adhesive 4, thereby bonding a heatsink plate 1 and the rear face of the semiconductor chip 2 to each other.

It should be understood that the present invention may be carried out in any manner other than specifically described above as embodiments, and many modifications and variations are possible within the scope and spirit of the present invention. For example, any combination of the above described embodiments (e.g., the first and seventh embodiments) makes it possible to provide a semiconductor device and a semiconductor module having even higher heat dissipation efficiency.

What is claimed is:

1. A semiconductor device comprising:
a plate-shaped semiconductor chip; and
a heatsink plate that is fitted to a rear face of the semiconductor chip with an adhesive laid therebetween,
wherein, in the rear face of the semiconductor chip, right under a heat generating portion thereof, there is formed a depressed portion.

2. The semiconductor device of claim 1, wherein, in the heatsink plate, there is formed a protruding portion that is fitted in the depressed portion.

3. The semiconductor device of claim 1, wherein the depressed portion is formed to have a hemispherical surface.

4. The semiconductor device of claim 1, wherein the depressed portion is formed to be a groove having a V-letter shape in cross-section.

5. The semiconductor device of claim 1, wherein the heat generating portion is an electrode area formed on the front face of the semiconductor chip.

6. A semiconductor module comprising: the semiconductor device of claim 1; a lead terminal; a wire for electrically connecting the electrode formed on the front face of the semiconductor chip and the lead terminal; and a mold resin for sealing the semiconductor device, the lead terminal, and the wire.

7. The semiconductor device of claim 2, wherein the depressed portion is formed to have a hemispherical surface.

8. The semiconductor device of claim 2, wherein the depressed portion is formed to be a groove having a V-letter shape in cross-section.

9. The semiconductor device of claim 2, wherein the heat generating portion is an electrode area formed on the front face of the semiconductor chip.

10. A semiconductor module comprising: the semiconductor device of claim 2; a lead terminal; a wire for electrically connecting the electrode formed on the front face of the semiconductor chip and the lead terminal; and a mold resin for sealing the semiconductor device, the lead terminal, and the wire.

11. The semiconductor device of claim 3, wherein the heat generating portion is an electrode area formed on the front face of the semiconductor chip.

12. A semiconductor module comprising: the semiconductor device of claim 3; a lead terminal; a wire for electrically connecting the electrode formed on the front face of the semiconductor chip and the lead terminal; and a mold resin for sealing the semiconductor device, the lead terminal, and the wire.

13. The semiconductor device of claim 4, wherein the heat generating portion is an electrode area formed on the surface of the semiconductor chip.

14. A semiconductor module comprising: the semiconductor device of claim 4; a lead terminal; a wire for electrically connecting the electrode formed on the front face of the semiconductor chip and the lead terminal; and a mold resin for sealing the semiconductor device, the lead terminal, and the wire.

15. The semiconductor device of claim 5, wherein, right under a connection portion which is located in the electrode area and to which the wire is connected, the depressed portion is formed.

16. A semiconductor module comprising: the semiconductor device of claim 5; a lead terminal; a wire for electrically connecting the electrode formed on the front face of the semiconductor chip and the lead terminal; and a mold resin for sealing the semiconductor device, the lead terminal, and the wire.

17. A semiconductor module comprising: the semiconductor device of claim 15; a lead terminal; a wire for electrically connecting the electrode formed on the front face of the semiconductor chip and the lead terminal; and a mold resin for sealing the semiconductor device, the lead terminal, and the wire.
